(19) United States
(12) Patent Application Publication
(10) Pub. No.: US 2009/0038537 A1
(43) Pub. Date: Feb. 12, 2009

(54) METHOD OF PULLING UP SILICON SINGLE CRYSTAL

(75) Inventor: Toshiro MINAMI, Shibata-shi (JP)

Correspondence Address: FOLEY AND LARDNER LLP;SUITE 500, 3000 K STREET NW, WASHINGTON, DC, 20007, US

(73) Assignee: COVALENT MATERIALS CORPORATION

(21) Appl. No.: 12/186,063

(22) Filed: Aug. 5, 2008

(30) Foreign Application Priority Data
Aug. 7, 2007 (JP) 2007-204845
Jun. 12, 2008 (JP) 2008-153677

(51) Int. Cl. C30B 15/00

(52) U.S. Cl. 117/13

(57) ABSTRACT

A method of pulling up a silicon single crystal is provided in which a variation rate of a neck diameter is controlled to be within a predetermined range, and a dislocation in a neck is eliminated. When pulling up the silicon single crystal, a single crystal with a predetermined crystal diameter is grown by bringing a seed crystal into contact with a material silicon melt, pulling up the seed crystal, growing the neck, and then increasing a diameter. The above-mentioned neck diameter is increased and decreased to grow the neck, during which a neck diameter variation rate is greater than or equal to 0.05 and less than 0.5, assuming that a value obtained in such a manner that a neck diameter difference (A−B) between adjoining inflection points is divided by a neck length L between the above-mentioned inflection points P1 and P2 is the neck diameter variation rate.

### BACKGROUND OF THE INVENTION

1. Field of the Invention

The present invention relates to a method of pulling up a silicon single crystal by the Czochralski method (the Magnetic field applied Czochralski Method; hereinafter referred to as the MCZ method) in which a magnetic field is applied.

2. Description of the Related Art

As methods of manufacturing a silicon single crystal, the CZ method and the MCZ method in which the magnetic field is applied are widely used, since the single crystal with non-dislocation or very few crystal defects can be obtained comparatively easily, allowing a large caliber and high purity.

For the manufacture of the silicon single crystal by the CZ method, in a single crystal pull-up apparatus as shown in FIG. 2 (for example), in a hot zone heated by a heater 7 and kept warm by a heat insulator 8 within a chamber 9, a seed crystal 1 made of a silicon single crystal is brought into contact with a material silicon melt 5 which is filled in a quartz crucible 6, then rotated and pulled up slowly to form a neck 2, subsequently a shoulder part 3 whose crystal diameter is gradually increased and a straight body with a constant diameter are formed. Thus, a silicon single crystal 4 is grown through these formation processes.

Conventionally, in the above-described CZ method, the neck is thinly formed to have a diameter of approximately 3 mm in order to eliminate a dislocation resulting from the seed crystal, and a dislocation introduced by a thermal shock at the time of contacting the melt.

However, in recent years, it has been required to manufacture the silicon single crystal with high weight for obtaining a large diameter wafer as a semiconductor device has been highly integrated, the costs have been reduced, and manufacturing efficiency has been improved. A conventional small diameter neck does not allow high weight of a single crystal ingot, but there is a possibility that it may break and lead to a serious accident, for example, the single crystal ingot may fall.

To cope with this, for example, Japanese Patent Application Publication (KOKAI) No. H9-249482 (patent document 1) discloses that a rotation speed of the seed crystal at the time of neck formation is set to 1-12 rpm which is lower than that at the time of straight body formation, whereby natural convection caused by the rotation of the seed crystal may be controlled, a shape of a growth interface of the crystal may be more convex downwardly, and the dislocation can be eliminated even if the diameter of the neck is not so reduced.

Further, Japanese Patent Application Publication (KOKAI) No. 2004-83320 (patent document 2) discloses that the crucible rotation speed in the neck formation process is set to 1 rpm or less, a magnetic field of 0.1 teslas or less is applied horizontally, and the application of the magnetic field is stopped at a stage of shifting to a diameter increasing process, whereby the possible dislocation can be prevented.

Furthermore, Japanese Patent Application Publication (KOKAI) No. H7-300388 (patent document 3) discloses that a length of a tapered narrowing part following the seed crystal is set to 2.5 to 15 times the diameter of the seed crystal, a diameter of a narrow part having a substantially constant diameter following this tapered narrowing part is set to 0.09 to 0.9 times the diameter of the seed crystal, variations are 1 mm or less, the length of the narrow part is set to 200-600 mm, and a transverse magnetic field of 1000-5000 gausses is applied.

Still further, Japanese Patent Application Publication (KOKAI) No. H11-199384 (patent document 4) discloses that the diameter of the neck is increased and decreased, the neck is formed in a so-called corrugation shape, and a variation of the neck diameter per unit length is set to 0.5 mm/mm or more, so that the dislocation can be prevented from generating.

However, as described above in the above-mentioned patent document 1, even in the case where the crystal rotation is changed when the small neck having a crystal diameter of approximately 3-6 mm is formed, a degree of the downward convexity in the crystal growth interface does not change considerably. Rather, it is possible to say that a change in pull-up speed provides a dislocation elimination effect, but when forming the small diameter neck as described above, the effect of eliminating the dislocation by controlling the degree of the downward convexity is small.

Further, when magnetic field intensity of the transverse magnetic field is 0.1 teslas or less like the method as described above in patent document 2, in the case of a large quantity of material silicon melt, it is not possible to sufficiently inhibit the natural convection and a temperature variation of the melt caused by the natural convection.

Furthermore, in the method as described above in patent document 3, it is effective for dislocation control to prepare the narrowing part, however long working hours are required for forming the long neck part as described above, which is not preferred in practice. It should be noted that a range of variation in the diameter of the narrowing part means the concavo-convex width of its surface, prevents plastic deformation due to stress concentration, and is merely shown in terms of obtaining sufficient intensity.

Still further, in the method as described above in patent document 4, the large variation of the neck diameter increases the temperature gradient of the outer surface of the neck at the time of reducing the diameter, and increases a dislocation density. Conversely, the dislocation may become difficult to disappear. Especially in the MCZ method, in the case where liquid melt convection is inhibited, a periodical variation of the melt surface temperature, referred to as a spoke pattern, appears significantly, and the variation of the neck diameter becomes too large to realize non-dislocation.

### SUMMARY OF THE INVENTION

The present invention has been made since it has been found that it is effective not only to cause a solid-liquid interface of a single crystal which is pulled up to be convex downwardly, but also to grow a neck within a specific conditional range of diameter variations of a neck, in order to remove a dislocation in the neck at an early stage.

In other words, the present invention aims at providing a method of pulling up a silicon single crystal in which a variation rate of neck diameters is controlled to be within a predetermined range, and the dislocation in the neck can be eliminated at an early stage, when a silicon single crystal is grown by the MCZ method.

The method of pulling up the silicon single crystal in accordance with the present invention is characterized by bringing a seed crystal into contact with a material silicon melt, pulling up the seed crystal, growing a neck, and then increasing a diameter to grow a single crystal with a predetermined crystal diameter, wherein the above-mentioned neck diameter is increased and decreased to grow the neck, during which a neck diameter variation rate is greater than or equal to 0.05 and less than 0.5, assuming that a quotient of a neck diameter difference between adjoining inflection points of the above-mentioned increasing and decreased neck diameter over a neck length between the above-mentioned inflection points is the neck diameter variation rate.

By controlling the neck diameter variation as described above, and growing the neck, the dislocation can be eliminated at an early stage.

It is preferable that when growing the above-mentioned neck, a cusp magnetic field of 100 gausses or more is applied to a crucible wall, a crystal rotation speed is between 1 rpm and 15 rpm (inclusive), and a crucible rotation speed of a crucible rotating in the opposite sense to the above-mentioned crystal is between 8 rpm and 15 rpm (inclusive).

Alternatively, it is preferable that when growing the above-mentioned neck, a transverse magnetic field of 2000 gausses or more is applied, the crystal rotation speed is between 1 rpm and 15 rpm (inclusive), and the crucible rotation speed of the crucible rotating in the opposite sense to the above-mentioned crystal is between 0.5 rpm and 3 rpm (inclusive).

By growing the neck on such magnetic field application conditions, it is possible to control the temperature variation in a long cycle which affects the neck diameter, and control the neck diameter variation efficiently.

As described above, according to the method of pulling up the silicon single crystal in accordance with the present invention, when growing the silicon single crystal by the CZ method, it is possible to control the neck diameter variation rate, and eliminate the dislocation in the neck at an early stage.

Therefore, according to the pull-up method in accordance with the present invention, it is possible to shorten the neck forming process and reduce a production time loss even in the case where redo due to a poor neck is performed.

### BRIEF DESCRIPTION OF THE DRAWINGS

FIG. 1 is a schematic diagram for explaining a neck diameter variation rate.

FIG. 2 is a schematic cross sectional view for explaining growth of a silicon single crystal in a single crystal pull-up apparatus.

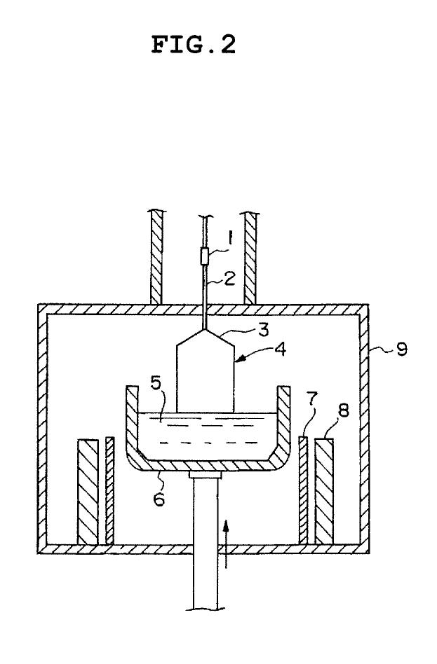

FIG. 3 is a table showing results of Examples and Comparative examples.

### DESCRIPTION OF THE PREFERRED EMBODIMENTS

Hereafter, the present invention will be described in detail.

A method of pulling up a silicon single crystal in accordance with the present invention is characterized by bringing a seed crystal into contact with a material silicon melt, pulling up the seed crystal, growing a neck, and then increasing a diameter to grow a single crystal with a predetermined crystal diameter, wherein the above-mentioned neck diameter is increased and decreased to grow the neck, during which a neck diameter variation rate is greater than or equal to 0.05 and less than 0.5.

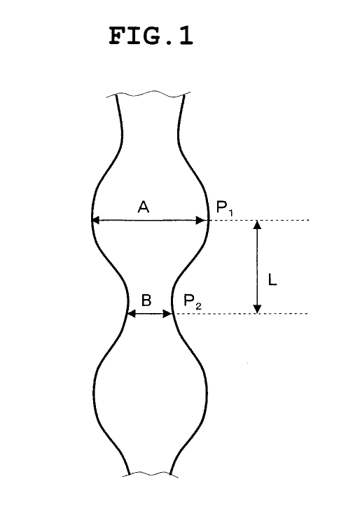

In the present invention, by the neck diameter variation rate is meant a value (quotient) obtained in such a manner that a neck diameter difference (A−B) between an increased neck diameter A and a decreased neck diameter B between adjoining inflection points P1 and P2 is divided by a neck length between the above-mentioned inflection points P1 and P2 in the increasing and decreasing neck diameters as shown in FIG. 1.

When the neck diameter increases or decreases, the maximum stress takes place on the neck perimeter. In the case where this exceeds the limit of dislocation control, a dislocation density increases and it becomes difficult to eliminate the dislocation in the neck.

For this reason, it is preferable that the neck diameter is constant. In fact, however, it is not possible to inhibit the variation of the neck diameter completely because of the temperature variation of the material silicon melt.

On the other hand, in the present invention, by growing the neck so that the above-mentioned neck diameter variation rate may be greater than or equal to 0.05 and less than 0.5, the dislocation can be eliminated at an early stage and the non-dislocation can be realized in a short time.

In order to control the above-mentioned neck diameter variation rate to be greater than or equal to 0.05 and less than 0.5, it is effective to control the temperature variation of a material silicon melt surface with which the neck is brought into contact, and in particular to control the temperature variation in a comparatively long cycle which affects the neck diameter.

When pulling up the single crystal by the CZ method where the magnetic field is not applied or in the cusp magnetic field, it is effective to increase the crucible rotation speed as long as the single crystal can be stably pulled up.

It should be noted that, by the MCZ method in which an amount of liquid melt exceeds 100 kg, it is substantially impossible to control the above-mentioned neck diameter variation rate to be less than 0.05 within a certain neck length.

As described above, in terms of controlling the temperature variation in a comparatively long cycle which affects the neck diameter, it is preferable to apply the cusp magnetic field to the crucible wall so that it may be 100 gausses or more when growing the above-mentioned neck, in order to control the heat convection of the material silicon melt. In this case, it is preferable that the crucible rotation speed is greater than 8 rpm and less than or equal to 15 rpm.

In the case where the cusp magnetic field at the above-mentioned crucible wall is less than 100 gausses, the effect of controlling the liquid melt convection is not sufficiently obtained.

Further, in the case where the above-mentioned crucible rotation speed is 8 rpm or less, a low-temperature portion at the material silicon melt surface or a band-like low-temperature area referred to as a so-called spoke pattern becomes remarkable. When this low-temperature portion crosses a neck growing portion which is in the center of the silicon material melt surface, the neck diameter varies, it becomes difficult to maintain the above-mentioned neck diameter variation rate to be less than or equal to 0.5, and the neck may be too thick, or conversely, too thin, leading to breakage.

On the other hand, in the case where the crucible rotation speed exceeds 15 rpm when growing the neck, at the time of growing a shoulder part and a straight body after growing the neck, the crucible rotation speed is usually reduced to 10 rpm or less in order to control an oxygen concentration. This rapid change in rotation speed causes convection disorder, and the crystal is dislocated easily.

Alternatively, a system of applying the magnetic field when growing the above-mentioned neck may be of the transverse magnetic field. In this case, in order to stabilize the neck diameter and to control the temperature variation in a long cycle at the material silicon melt, it is preferable that the magnetic field intensity is 2000 gausses or more and the crucible rotation speed is between 0.5 rpm and 3 rpm (inclusive).

In the case where the above-mentioned magnetic field intensity is less than 2000 gausses, the control of the material silicon melt convection by the magnetic field is insufficient, the low-temperature portion occurred in parallel with a direction of the magnetic field may cross the neck growing portion, causing the neck diameter to vary. Thus, it is difficult to control the variation rate to be 1.0 or less.

Further, in the case of the transverse magnetic field, when the crucible rotation speed exceeds 3 rpm, the temperature variation of the material silicon melt becomes large, the neck diameter is not stable, and the growth at a constant diameter portion (straight body) is not stable, either. For this reason, preferably the crucible rotation speed is lower, however it is preferably 0.5 rpm or more in terms of the single crystal growing efficiency.

Furthermore, in terms of stably maintaining the neck diameter, the rotation speed of the crystal which rotates in the opposite sense to the above-mentioned crucible may only be 1 rpm or more in the case of applying the magnetic field, either the cusp magnetic field or the transverse magnetic field. However, when growing the shoulder part and the straight body after the neck growing process, it is necessary to reduce the crystal rotation in order to inhibit them from being deformed. In the case where the above-mentioned rotation speed exceeds 15 rpm, the conditions need to be changed rapidly, leading to a possibility of dislocation, which is not preferred.

### EXAMPLES

Hereafter, the present invention will be described more particularly with reference to Examples, but the present invention is not limited to the following Examples.

### Examples 1-6

### Comparative Examples 1-5

100 kg of material silicon melt is filled in a quartz crucible having a diameter of 24 inches. By means of a CZ method single crystal pull-up apparatus, a neck was grown so as to have an average neck diameter of 4.5 mm, and a silicon single crystal was grown.

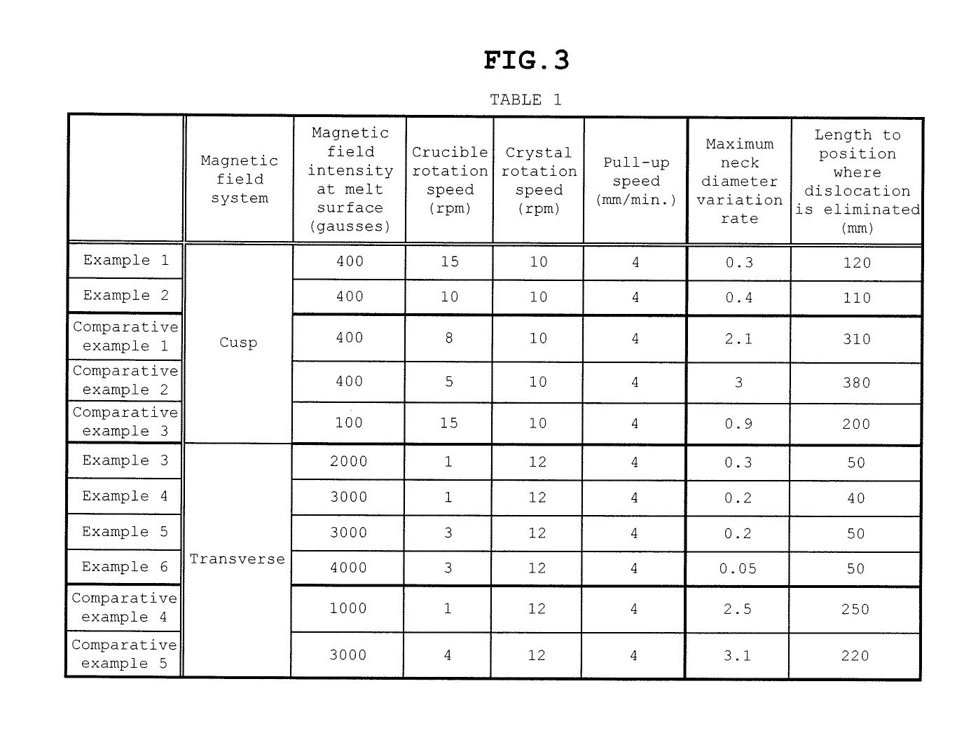

When growing the neck, the magnetic field application, crucible rotation speed, crystal rotation speed, and single crystal pull-up speed were as shown in Examples 1-6 and Comparative Examples 1-5 of Table 1 shown in FIG. 3, respectively.

Measured for each Example are the maximum neck diameter variation rate and a length from a growth starting position to a position where dislocation was eliminated.

These results are collectively shown in Table 1 of FIG. 3.

It should be noted that the measured values of magnetic field intensity were at the crucible wall in the case of the cusp magnetic field, and the center in the case of the transverse magnetic field. The neck diameter was measured with a vernier caliper. Further, the length from the growth starting position to the position where the dislocation was eliminated was judged by visually measuring the dislocation in compliance with the etching evaluation (JIS H 0609) with selective etching liquid.

As can be seen from Table 1 of FIG. 3, in the case where either the cusp magnetic field or the transverse magnetic field was applied, it was pulled up under predetermined conditions, thus it was possible to control the neck diameter variation rate to be greater than or equal to 0.05 and less than 0.5. In this case, it was confirmed that the dislocation could be eliminated at an early stage.

What is claimed is:

1. A method of pulling up a silicon single crystal, bringing a seed crystal into contact with a material silicon melt, pulling up the seed crystal, growing a neck, and then increasing a diameter to grow a single crystal with a predetermined crystal diameter, wherein said neck diameter is increased and decreased to grow the neck, during which a neck diameter variation rate is greater than or equal to 0.05 and less than 0.5, assuming that a quotient of a neck diameter difference between adjoining inflection points of said increasing and decreased neck diameter over a neck length between said inflection points is said neck diameter variation rate.

2. The method of pulling up the silicon single crystal according to claim 1, wherein when growing said neck, a cusp magnetic field of 100 gausses or more is applied to a crucible wall, a crystal rotation speed is between 1 rpm and 15 rpm (inclusive), and a crucible rotation speed of a crucible rotating in the opposite sense to said crystal is between 8 rpm and 15 rpm (inclusive).

3. The method of pulling up the silicon single crystal according to claim 1, wherein when growing said neck, a transverse magnetic field of 2000 gausses or more is applied, a crystal rotation speed is between 1 rpm and 15 rpm (inclusive), and a crucible rotation speed of a crucible rotating in the opposite sense to said crystal is between 0.5 rpm and 3 rpm (inclusive).
